(19) United States
(12) Patent Application Publication
(10) Pub. No.: US 2013/0038343 A1
(43) Pub. Date: Feb. 14, 2013

(54) TEST CIRCUIT FOR TESTING SHORT-CIRCUIT

(71) Applicants: YI-XIN TU, Shenzhen City (CN); JIN-LIANG XIONG, Shenzhen City (CN); HAI-QING ZHOU, Shenzhen City (CN)

(72) Inventors: YI-XIN TU, Shenzhen City (CN); JIN-LIANG XIONG, Shenzhen City (CN); HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/275,374

(22) Filed: Oct. 18, 2011

(30) Foreign Application Priority Data
Aug. 9, 2011 (CN) 201110226895.7

(51) Int. Cl. G01R 31/20; G01R 31/02

(52) U.S. Cl. 324/754.03; 324/537

(57) ABSTRACT

A test circuit includes two probes, a comparison circuit, a switch circuit, and an indication circuit. The probes are connected to an electronic component to be tested, and a low level signal is output if the electronic component is short-circuited. The comparison circuit outputs a comparison signal based on the shorting signal from the probes. The switch circuit outputs a switch signal based on the comparison signal from the comparison circuit. The indication circuit indicates that the electronic component is short-circuited or not short-circuited based on the switch signal fro m the switch circuit.

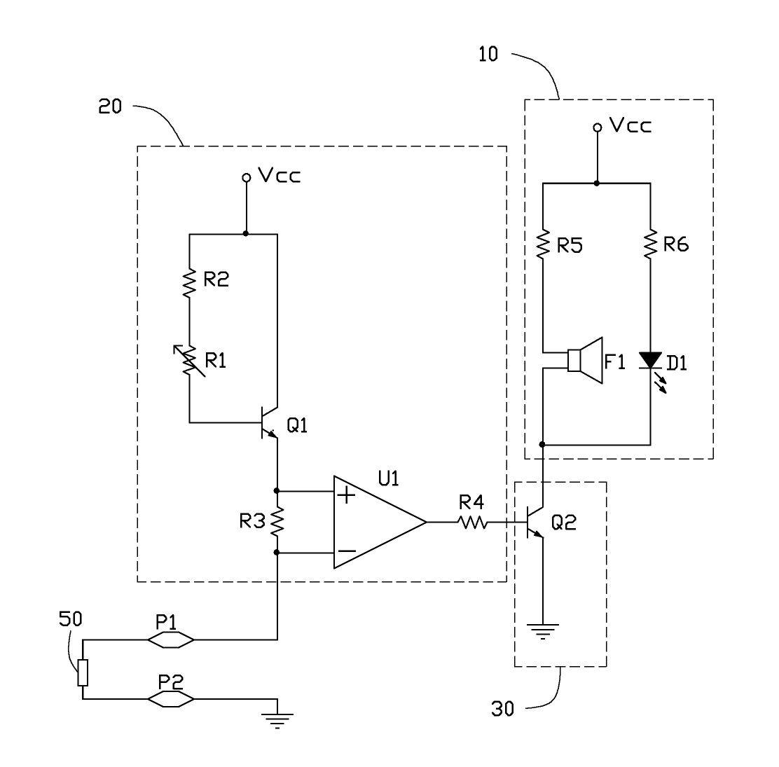

### BACKGROUND

1. Technical Field

The present disclosure relates to a test circuit for testing short-circuit.

2. Description of Related Art

A power supply circuit supplying power for a central processing unit includes a number of transistors and a number of capacitors. The transistors and capacitors may be short-circuited for a number of reasons, such as problems in soldering. In test, we can not find out the shorted-circuit transistor or capacitor rapidly and accurately by a normal test means.

### BRIEF DESCRIPTION OF THE DRAWING

Many aspects of the present embodiments can be better understood with reference to the drawing. The components in the drawing are not necessarily drawn to scale, the emphasis instead being placed upon clearly illustrating the principles of the present embodiments. Moreover, in the drawing, the view is schematic.

The FIGURE is a circuit diagram of an exemplary embodiment of a testing circuit.

### DETAILED DESCRIPTION

The disclosure is illustrated by way of example and not by way of limitation in the figures of the accompanying drawing. References to “an” or “one” embodiment in this disclosure are not necessarily to the same embodiment, and such references mean at least one.

The FIGURE is an exemplary embodiment of a circuit for testing whether an electronic component 50, such as a capacitor, is short-circuited. The test circuit includes a comparison circuit 20, an indication circuit 10, a switch circuit 30, and first and second probes P1 and P2. The probes P1 and P2 are connected to the indication circuit 10 through the comparison circuit 20 and through the switch circuit 30 in that order.

A first end of the first probe P1 is connected to the comparison circuit 20. A first end of the second probe P2 is grounded. The second end of each probe P1 and P2 makes contact with opposite ends of the electronic component 50. If the electronic component 50 is not short-circuited, the electronic component 50 prevents a direct ground connection to the first probe P1, and no signal of any kind is output.

The comparison circuit 20 outputs a comparison signal based on a low level voltage signal from the probe P1.

The switch circuit 30 outputs a switch signal based on the comparison signal from the comparison circuit 20.

The indication circuit 10 indicates either that the electronic component 50 is short-circuited or is not short-circuited based on the switch signal from the switch circuit 30.

In detail, the comparison circuit 20 includes a transistor Q1, a comparator U1, a variable resistor R1, and resistors R2-R4. The base of the transistor Q1 is connected to a direct current (DC) power VCC through the variable resistor R1 and the resistor R2 in series. The collector of the transistor Q1 is connected to the DC power VCC. The emitter of the transistor Q1 is connected to a non-inverting terminal of the comparator U1. The non-inverting terminal of the comparator U1 is also connected to the inverting terminal of the comparator U1 through the resistor R3. The inverting terminal of the comparator U1 is connected to the first end of the first probe P1. The output of the comparator U1 is connected to a first terminal of the resistor R4.

The switch circuit 30 includes a transistor Q2. The base of the transistor Q2 is connected to a second terminal of the resistor R4, and the emitter of the transistor Q2 is grounded.

The indication circuit 10 includes a speaker F1, a light emitting diode (LED) D1, and resistors R5 and R6. A first terminal of the speaker F1 and the cathode of the LED D1 are connected to the collector of the transistor Q2. The second terminal of the speaker F1 is connected to the DC power VCC through the resistor R5. The anode of the LED D1 is connected to the DC power VCC through the resistor R6.

In use, if the electronic component 50 is short-circuited, the probe P1 pulls the inverting terminal of the comparator U1 to ground. The voltage of the non-inverting terminal of the comparator U1 is thus at a higher level than the voltage at the inverting input. The output of the comparator U1 outputs a high level voltage signal to the base of the transistor Q2, and transistor Q2 turns on. The speaker F1 and the LED D1 are powered on, therefore the speaker F1 will buzz and the LED D1 will light to indicate that the electronic component 50 is short-circuited.

If the electronic component 50 is not short-circuited, the first probe P1 will not be grounded. The output of the comparator U1 outputs a low level signal. The low level signal to the base of the transistor Q2 turns it off. The speaker F1 and the LED D1 remain in a turned off state indicating that the electronic component 50 is not short circuited.

The impedance of the variable resistor R1 can be adjusted to control the current flowing through the emitter of the transistor Q1. In other words, the variable resistor R1 may be used to amplify the voltage across the resistor R3.

Although numerous characteristics and advantages of the present disclosure have been set forth in the foregoing description, together with details of the structure and function of the disclosure, the disclosure is illustrative only, and changes may be made in details, especially in the matters of shape, size, and arrangement of parts within the principles of the disclosure to the full extent indicated by the broad general meaning of the terms in which the appended claims are expressed.

What is claimed is:

1. A test circuit for testing whether an electronic component is short-circuited, the test circuit comprising:
two probes for contacting opposite ends of the electronic component, and outputting a shorting signal in response to the electronic component being short-circuited;
a comparison circuit outputting a comparison signal based on the shorting signal from the probes;
a switch circuit outputting a switch signal based on the comparison signal from the comparison circuit; and
an indication circuit for indicating that the electronic component is short-circuited or is not short-circuited based on the switch signal from the switch circuit.

2. The test circuit of claim 1, wherein the probes comprises a first probe and a second probe, first ends of the first and second probes are used for contacting the ends of the electronic component, a second end of the second probe is grounded, and a second end of the first probe outputs the shorting signal in response to the electronic component being short-circuited, the shorting signal is a low level voltage signal.

3. The test circuit of claim 2, wherein the comparison circuit comprises a first transistor, a comparator, and first to third resistors, a base of the first transistor is connected to a direct current (DC) power source through the first resistor, a collector of the first transistor is connected to the DC power source, an emitter of the first transistor is connected to a non-inverting terminal of the comparator, the non-inverting terminal of the comparator is also connected to an inverting terminal of the comparator through the second resistor, an output of the comparator is connected to a first terminal of the third resistor, a second terminal of the third resistor is connected to the switch circuit, the inverting of the comparator is also connected to the second terminal of the first probe.

4. The test circuit of claim 3, wherein the comparison circuit further comprises a variable resistor connected between the base of the first transistor and the first resistor.

5. The test circuit of claim 3, wherein the switch circuit comprises a second transistor, a base of the second transistor is connected to the second terminal of the third resistor, an emitter of the second transistor is grounded, a collector of the second transistor is connected to the indication circuit.

6. The test circuit of claim 5, wherein the indication circuit comprises a speaker, a light emitting diode (LED), a fourth resistor, and a fifth resistor, a first end of the speaker and a cathode of the LED are connected to the collector of the second transistor, a second end of the speaker is connected to the DC power source through the fourth resistor, an anode of the LED is connected to the DC power source through the fifth resistor.

7. The test circuit of claim 1, wherein the electronic component is a capacitor.
